(19) United States
(12) Patent Application Publication
(10) Pub. No.: US 2025/0123435 A1
(43) Pub. Date: Apr. 17, 2025

(54) OPTICAL FILM LAMINATE AND IMAGE DISPLAY DEVICE COMPRISING SAME

(71) Applicant: DONGWOO FINE-CHEM CO., LTD., Jeollabuk-do (KR)

(72) Inventors: JI HOON KONG, Gyeonggi-do (KR); DONG DUK CHOI, Gyeonggi-do (KR); SEUNG HEE KIM, Gyeonggi-do (KR); GEO SAN LIM, Seoul (KR)

(21) Appl. No.: 18/695,969

(22) PCT Filed: Sep. 15, 2022
(86) PCT No.: PCT/KR2022/013764

§ 371 Date: Mar. 27, 2024

(30) Foreign Application Priority Data
Sep. 30, 2021 (KR) 10-2021-0129387

(51) Int. Cl. G02B 5/30

(52) U.S. Cl. CPC G02B 5/3083; G02B 5/305

(57) ABSTRACT

An optical film laminate includes a phase retardation layer, a polarizing layer laminated on the phase retardation layer, and a barrier layer disposed between the phase retardation layer and the polarizing layer or under the phase retardation layer. Iodine migrated from the polarizing layer is blocked by the barrier layer, and thus metallic members included in an image display device can be protected from corrosion.

### CROSS REFERENCE TO RELATED APPLICATIONS AND CLAIM OF PRIORITY

This application claims benefit under 35 U.S.C. 119, 120, 121, or 365 (c), and is a National Stage entry from International Application No. PCT/KR2022/013764 filed on Sep. 15, 2022, which claims priority to the benefit of Korean Patent Application No. 10-2021-0129387 filed on Sep. 30, 2021, in the Korean Intellectual Property Office, the entire contents of which are incorporated herein by reference.

### BACKGROUND

### 1. Technical Field

The present invention relates to an optical film laminate and an image display device including the same. More particularly, the present invention relates to an optical film laminate including a polarizing layer and an image display device including the same.

### 2. Background Art

For example, an optical film such as a retardation film, a polarizing film, a luminance enhancing film, etc., may be inserted into an image display device such as a liquid crystal display (LCD), an organic light emitting diode (OLED) display, etc. The optical film may include a polyvinyl alcohol (PVA)-based polarizer that may be dyed and stretched.

The optical film may be stacked on a touch panel included in the image display device. In this case, components included in the polarizer, an adhesive layer, etc., may be diffused downward to penetrate into the touch panel. Accordingly, a metal layer such as a wiring, an electrode, etc., included in the touch panel may be corroded.

Additionally, according to recent developments of a thin-layered display having flexible properties, developments of an optical film having improved flexible or foldable properties are also needed. Thus, an introduction of an optical film having a thinned structure and improved chemical and mechanical stability is required in the image display device.

For example, Korean Published Patent Application No. 10-2014-0135739 discloses an optical film including a polarizer and a retardation plate, but does not consider the corrosion prevention of the above-described touch sensor electrode.

### SUMMARY

According to an aspect of the present invention, there is provided an optical film laminate having improved chemical and mechanical reliability.

According to an aspect of the present invention, there is provided an image display device including an optical film laminate having improved chemical and mechanical reliability.

1. An optical film laminate, including: a retardation layer; a polarizing layer stacked on the retardation layer; and a barrier layer disposed between the retardation layer and the polarizing layer, or under the retardation layer.

2. The optical film laminate of the above 1, wherein the retardation layer includes a first retardation layer including a half-wavelength retardation layer and a second retardation layer including a quarter-wavelength retardation layer.

3. The optical film laminate of the above 2, further including a first adhesive layer formed between the polarizing layer and the first retardation layer, and a second adhesive layer formed between the first retardation layer and the second retardation layer.

4. The optical film laminate of the above 3, wherein the barrier layer is disposed between the second adhesive layer and the second retardation layer.

5. The optical film laminate of the above 3, wherein the barrier layer is disposed between the polarizing layer and the first adhesive layer.

6. The optical film laminate of the above 3, wherein the barrier layer is disposed between the first adhesive layer and the first retardation layer.

7. The optical film laminate of the above 3, wherein the barrier layer is disposed between the first retardation layer and the second adhesive layer.

8. The optical film laminate of the above 3, further including a third adhesive layer formed on a bottom surface of the second retardation layer.

9. The optical film laminate of the above 8, wherein the barrier layer is disposed between the third adhesive layer and the second retardation layer.

10. The optical film laminate of the above 8, wherein an amount of iodine in the third adhesive layer measured by a time-of-flight secondary ion mass spectrometry (TOF-SIMS) after being left for 250 hours at 85° C. and a relative humidity of 85% is 3.5*10⁻⁴ counts or less.

11. The optical film laminate of the above 8, wherein an amount of iodine in the third adhesive layer measured by a time-of-flight secondary ion mass spectrometry (TOF-SIMS) after being left for 250 hours at 85° C. and a relative humidity of 85% is 2.4*10⁻⁴ counts or less.

12. The optical film laminate of the above 1, wherein a thickness of the barrier layer is in a range from 1 to 7 μm.

13. The optical film laminate of the above 1, wherein the barrier layer includes a cycloaliphatic acrylic resin.

14. The optical film laminate of the above 1, wherein the polarizing layer includes a polyvinyl alcohol (PVA) polarizer dyed with iodine, and the barrier layer serves as an iodine migration blocking layer.

15. An image display device, including: a display panel; and the optical film laminate of the above-described embodiments stacked on the display panel.

16. The image display device of the above 15, further including a touch sensor layer disposed between the display panel and the optical film laminate.

An optical film according to embodiments of the present invention may include a polarizer and a retardation layer, and may further include a barrier layer. The barrier layer may be disposed between the polarizer and the retardation layer or between different retardation layers. Accordingly, downward transfer and penetration of iodine contained in the polarizer may be blocked, and corrosion of metallic members disposed at lower portion of the optical film may be prevented.

In some embodiments, the barrier layer may be disposed under an adhesive layer to effectively block an acceleration of an iodine migration by moisture, etc., included in the adhesive layer, and to prevent adhesive components and moisture from being transferred to the lower portion.

In some embodiments, the barrier layer may include an alicyclic (meth)acrylate-based ultraviolet curable polymer. Accordingly, an iodine migration may be prevented from being promoted by the thermal process, and to further suppress an affinity between iodine and moisture.

### BRIEF DESCRIPTIONS OF THE DRAWINGS

FIG. 1 is a schematic cross-sectional view illustrating an optical film laminate in accordance with example embodiments.

FIGS. 2 to 5 are schematic cross-sectional views illustrating optical film laminates in accordance with some example embodiments.

FIG. 6 is a schematic cross-sectional view illustrating an image display device in accordance with embodiments.

### DETAILED DESCRIPTION

According to embodiments of the present invention, an optical film including a polarizing layer, a retardation layer and a barrier layer and having improved optical and chemical reliability is provided. According to configurations of the present invention, an image display device including the optical film is provided.

Hereinafter, embodiments of the present invention will be described in more detail with reference to the accompanying drawings. However, the drawings attached herewith illustrate preferred embodiments of the present invention, and serve to further understand the technical spirit of the present invention together with the above-described contents, and the present invention should not be construed as being limited to details described in such drawings.

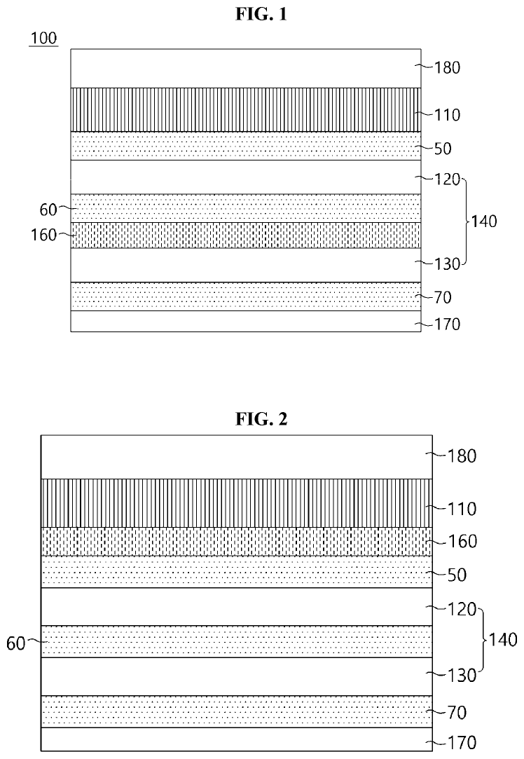

FIG. 1 is a schematic cross-sectional view illustrating an optical film in accordance with example embodiments.

Referring to FIG. 1, an optical film 100 may include a polarizing layer 110 and a retardation layer 140. The retardation layer 140 and the polarization layer 110 may be adhered to each other by a first adhesive layer 50.

In example embodiments, the polarization layer 110 may include a polarizer. In some embodiments, the polarizing layer 110 may include a stretchable polarizer in which a dichroic dye is adsorbed and oriented in a stretchable film.

The polarizing layer 110 may include a resin capable of being dyed with a dichroic dye, e.g., a polyethylene terephthalate resin, an ethylene-vinyl acetate copolymer, an ethylene-vinyl alcohol copolymer, a cellulose resin, a polyvinyl alcohol-based resin, etc.

Preferably, the polyvinyl alcohol-based resin may be used from aspects of uniformity of an in-plane polarization degree and an affinity for a dichroic material.

For example, the polarizing layer 110 may include a polyvinyl alcohol-based resin obtained by saponifying a polyvinyl acetate-based resin. The polyvinyl acetate-based resin may include a homopolymer of vinyl acetate or a copolymer of vinyl acetate and a monomer capable of being copolymerized therewith. The monomer capable of being copolymerized with vinyl acetate may include an unsaturated carboxylic acid monomer, an unsaturated sulfonic acid monomer, an olefinic monomer, a vinyl ether-based monomer, an acrylamide monomer having an ammonium group, etc.

The polarizing layer 110 may include a modified polyvinyl alcohol-based resin, e.g., polyvinyl formal or polyvinyl acetal modified by an addition of an aldehyde-based compound.

In an embodiment, the polarizer may be obtained by performing processes such as swelling, dyeing, cross-linking, stretching, washing, drying of a polyvinyl alcohol-based resin film.

The processes such as swelling, dyeing, cross-linking, stretching, washing, etc., may be performed while the film containing the polyvinyl alcohol-based resin is immersed in a constant temperature water bath.

Iodine may be used as the dichroic material in the dyeing process, and an iodide may be used as a dyeing aid. For example, the iodide may include potassium iodide, lithium iodide, sodium iodide, zinc iodide, aluminum iodide, lead iodide, copper iodide, barium iodide, calcium iodide, tin iodide, titanium iodide, etc.

In example embodiments, the retardation layer 140 may include a first retardation layer 120 and a second retardation layer 130.

The first retardation layer 120 may include a half-wavelength (λ/2) retardation layer. For example, the λ/2 retardation layer may refer to an optically anisotropic layer having an in-plane retardation (Re(λ)) of about λ/2 at a specific wavelength (e.g., 550 nm).

The first retardation layer 120 may include a cured product of a discotic liquid crystal compound. Non-limiting examples of the discotic liquid crystal compound may include materials described in Japanese Published Patent Application No. 2007-108732 or Japanese Published Patent Application No. 2010-244038.

The second retardation layer 130 may include a quarter-wavelength (λ/4) retardation layer. For example, the λ/4 retardation layer may refer to an optical anisotropic layer in which the in-plane retardation Re(λ) satisfies about λ/4 at a specific wavelength (e.g., 550 nm).

For example, the in-plane retardation Re(550) at a wavelength of 550 nm may be in a range from 115 nm to 155 nm, preferably from 120 nm to 145 nm. In the above range, light leakage of reflected light may be effectively suppressed when combined with the first retardation layer 120 that may be the λ/2 retardation layer.

In an embodiment, the second retardation layer 130 may include a cured product of a nematic liquid crystal compound. Non-limiting examples of the nematic liquid crystal compound may include a material disclosed in Japanese Published Patent Application No. H11-513019 or Japanese Published Patent Publication No. 2007-279688.

The polarizing layer 110 and the retardation layer 140 may be adhered by the first adhesive layer 50. For example, the first adhesive layer 50 may be disposed between a top surface of the first retardation layer 120 and a bottom surface of the polarizing layer 110.

The first adhesive layer 50 may be formed using an adhesive such as a pressure sensitive adhesive (PSA), an optically clear adhesive (OCA), an ultraviolet curable glue (UV-Glue), etc.

In an embodiment, the adhesive may be obtained from an adhesive composition including an acrylic copolymer and a crosslinking agent, or from an adhesive composition including a urethane (meth)acrylate resin, a (meth)acrylate ester monomer and a photo-initiator.

In one embodiment, the adhesive may include a photo-curable epoxy resin.

The first retardation layer 120 and the second retardation layer 130 may be adhered to each other by a second adhesive layer 60. The second adhesive layer 60 may include a material substantially the same as or similar to that of the first adhesive layer 50.

In example embodiments, the optical film laminate 100 may further include a barrier layer 160. The barrier layer 160 may be disposed under the polarizing layer 110 to prevent the dichroic dye included in the polarizing layer 110 from being propagated to a lower side (e.g., a display panel side or a touch panel side). Accordingly, the barrier layer 160 may be provided as an iodine transfer prevention layer.

Therefore, electrode/wiring included in the touch panel and the display panel may be prevented from being corroded according to the lower propagation of the iodine-based material.

The barrier layer 160 may also serve as a moisture absorbing layer or a moisture blocking layer. Additionally, organic components included in the adhesive layers 50 and 60 may be prevented from being diffused and propagated downward.

The barrier layer 160 may include a polymer material formed from an ultraviolet curable monomer. Accordingly, when the barrier layer 160 is formed, an increase of diffusion of the iodine-based material and propagation of moisture caused by a thermal curing may be suppressed.

In some embodiments, the barrier layer 160 may include a cycloaliphatic acrylic resin. For example, the barrier layer 160 may include an acrylic resin formed from an alicyclic (meth)acrylate-based monomer.

The barrier layer 160 may include the alicyclic polymer structure, so that hydrophobicity may be increased, and a carbon content in the barrier layer 160 may be increased, thereby further improving the blocking properties of the iodine-based material and moisture.

For example, the barrier layer 160 may include a polymer material formed from the alicyclic (meth)acrylate-based monomer such as tricyclodecane dimethanol diacrylate, cyclohexyl (meth)acrylate, etc.

As illustrated in FIG. 1, the barrier layer 160 may be disposed between the second adhesive layer 160 and the second retardation layer 130. Thus, movement of the dye material, moisture and organic material accelerated by the adhesive layers 50 and 60 may be effectively blocked while blocking the iodine-based material transfer from the polarizing layer 110.

The optical film laminate 100 may further include a lower protective film 170 and an upper protective film 180.

The lower protective film 170 may serve as a release layer. The lower protective film 170 may be adhered to the second retardation layer 130 by a third adhesive layer 70.

For example, after removing the lower protective film 170, the optical film laminate 100 may be stacked on the touch panel or the display panel using the third adhesive layer 70.

The upper protective film 180 may serve as a protective film of the polarizing plate. For example, a lower protective film of the polarizing plate may be removed from the polarizing plate including the upper protective film 180—the polarizer—the lower protective film, and the polarizer may be coupled to a top surface of the first retardation layer 120 by using the first adhesive layer 50.

The lower protective film 170 and the upper protective film 180 may include a polyester-based resin such as polyethylene terephthalate, polyethylene isophthalate and polybutylene terephthalate; a cellulose-based resin such as diacetyl cellulose and triacetyl cellulose; a polycarbonate-based resin; an acrylic resin such as polymethyl (meth)acrylate and polyethyl (meth)acrylate; a styrene-based resin such as polystyrene and an acrylonitrile-styrene copolymer; a polyolefin-based resin such as polyethylene, polypropylene, a cycloolefin or polyolefin having a norbornene structure and an ethylene-propylene copolymer; a vinyl chloride-based resin; an amide-based resin such as nylon and an aromatic polyamide; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane-based resin; a silicone-based resin, etc.

For example, the upper protective film 180 may include a cellulose-based film to maintain polarization properties and durability of the polarizing layer 110.

In some embodiments, the upper protective film 180 may have a multi-layered structure. For example, the upper protective film 180 may further include a window film or a hard coating film. For example, the optical film laminate 100 may serve as a display window-integrated film.

As described above, the barrier layer 160 may be inserted into the optical film laminate 100 to suppress the movement of iodine and to prevent transformation and corrosion of metal members or electrode members disposed under the optical film laminate 100.

In some embodiments, an amount of iodine in the third adhesive layer 70 of the optical film laminate 100 measured by a time-of-flight secondary ion mass spectrometry (TOF-SIMS) after being left at 85° C. and 85% relative humidity for 250 hours may be 3.5*10⁻⁴ counts or less. Preferably, the amount of iodine in the third adhesive layer 70 may be 2.4*10⁻⁴ counts or less, more preferably, 2.0*10⁻⁴ counts or less.

In some embodiments, a thickness of the barrier layer 160 may be in a range from 1 to 7 μm, preferably from 2 to 6 μm, more preferably from 3 μm or more and less than 5 μm.

In the above range, the iodine blocking effect by the barrier layer 160 may be substantially implemented. For example, if the thickness of the barrier layer 160 is excessively increased, the downward transfer of iodine downward may be rather increased.

In consideration of implementing a thin-layered structure and maintaining optical properties of the polarizing layer/retardation layer, the thickness of the barrier layer 160 may be smaller than each thickness of the adhesive layers 50, 60 and 70.

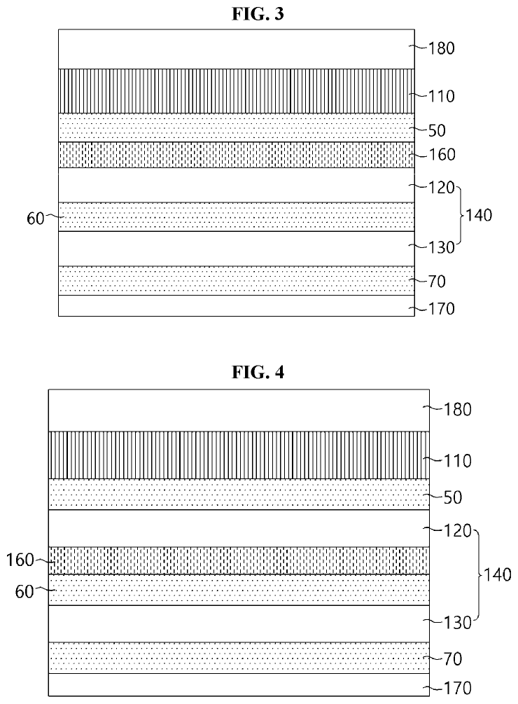

FIGS. 2 to 5 are schematic cross-sectional views illustrating optical film laminates in accordance with some example embodiments. Detailed descriptions of element and materials substantially the same as or similar to those described with reference to FIG. 1 are omitted.

Referring to FIG. 2, the barrier layer 160 may be disposed between the polarizing layer 110 and the first adhesive layer 50. Thus, the iodine transfer generated from the polarizing layer 110 may be directly blocked.

Referring to FIG. 3, the barrier layer 160 may be disposed between the first adhesive layer 50 and the first retardation layer 120. Accordingly, the iodine transfer accelerated by the first adhesive layer 50 may be blocked.

Referring to FIG. 4, the barrier layer 160 may be disposed between the first retardation layer 120 and the second adhesive layer 60.

Referring to FIG. 5, the barrier layer 160 may be disposed between the second retardation layer 130 and the third adhesive layer 70. In this case, propagation of the iodine component may be blocked at a position adjacent to the touch sensor.

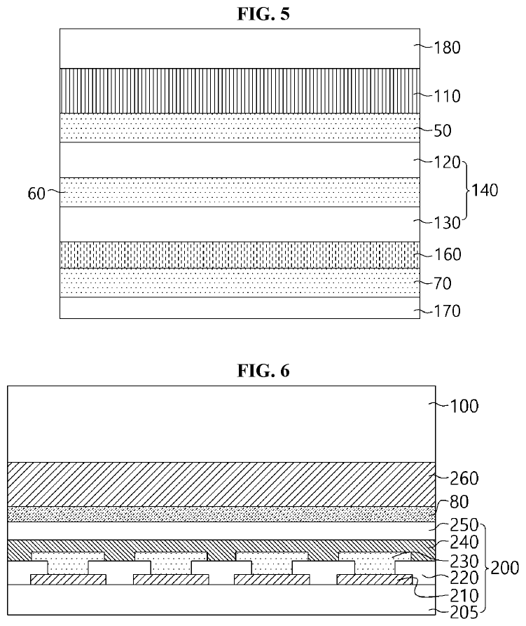

FIG. 6 is a schematic cross-sectional view illustrating an image display device in accordance with embodiments.

Referring to FIG. 6, an image display device may include a display panel 200 and the optical film laminate 100 stacked on the display panel 200.

The display panel 200 may include a pixel electrode 210, a pixel defining layer 220, a display layer 230, a counter electrode 240 and an encapsulation layer 250 disposed on a panel substrate 205.

A pixel circuit including a thin film transistor (TFT) may be formed on the panel substrate 205, and an insulation layer covering the pixel circuit may be formed. The pixel electrode 210 may be electrically connected to, e.g., a drain electrode of the TFT on the insulation layer.

The pixel defining layer 220 may be formed on the insulation layer to define a pixel region by exposing the pixel electrode 210. The display layer 230 is formed on the pixel electrode 210, and the display layer 230 may include, e.g., a liquid crystal layer or an organic light emitting layer.

The counter electrode 240 may be disposed on the pixel defining layer 220 and the display layer 230. The counter electrode 240 may serve as, e.g., a common electrode or a cathode of the image display device. The encapsulation layer 250 for protecting the display panel 200 may be stacked on the counter electrode 240.

In some embodiments, a touch sensor layer 260 may be stacked on the display panel 200. For example, the touch sensor layer 260 may be attached to the encapsulation layer 250 of the display panel 200 by a fourth adhesive layer 80.

In example embodiments, the optical film laminate 100 according to the above-described example embodiments may be stacked on the touch sensor layer 260.

For example, the lower protective film 170 of the optical film laminate 100 may be removed, and then the optical film laminate 100 may be attached to the touch sensor layer 260 by the third adhesive layer 70.

The touch sensor layer 260 may include sensing electrodes and traces connected to the sensing electrodes. As described above, the iodine component, the organic component, moisture, etc., which may diffuse and penetrate from an upper portion of the image display device may be blocked by the barrier layer 160 included in the optical film laminate 100 to prevent corrosion of the sensing electrodes and the traces.

Hereinafter, experimental examples including preferable examples and comparative examples are proposed to more concretely describe the present invention. However, the following examples are only given for illustrating the present invention and those skilled in the related art will obviously understand that various alterations and modifications are possible within the scope and spirit of the present invention. Such alterations and modifications are duly included in the appended claims.

### Example 1

A polarizing plate including a PVA polarizer (manufactured by Kuraray) having a thickness of 8 μm with a PET protective film attached to upper and lower portions of the polarizer was prepared, and a retardation layer laminate in which a half-wavelength retardation layer and a quarter-wavelength retardation layer (manufactured by Fuji Film) were attached using a 2 μm UV-Glu adhesive layer as a second adhesive layer was prepared. After forming a barrier layer on a top surface of the quarter-wavelength retardation layer, the barrier layer and the half-wavelength retardation layer were attached using the second adhesive layer (see the position of the barrier layer in FIG. 1).

The barrier layer was formed by coating a barrier composition prepared by mixing 26.5 parts by weight of cycloaliphatic acrylate (Mirmer M262, Miwon Specialty Chemical), 70 parts by weight of propylene glycol monoether, 3 parts by weight of 1-hydroxychlorohexylphenyl ketone, and 0.5 parts by weight of a silicon-based additive (BYK-307, BYK) on the half-wavelength retardation layer and then UV curing (thickness: 3.5 μm).

Thereafter, the lower protective film was removed from the polarizing plate, and the polarizer and the half-wavelength retardation layer were bonded by a PSA-based first adhesive layer (thickness: 5 μm).

A lower protective film (thickness: 38 μm) formed of a PET material was formed using a PSA-based third adhesive layer (thickness: 15 μm) to a bottom surface of the quarter-wavelength retardation layer.

### Example 2

An optical film laminate was manufactured by the same method as that in Example 1, except that the barrier layer was formed between the polarizer and the first adhesive layer (see FIG. 2).

### Example 3

An optical film laminate was manufactured by the same method as that in Example 1, except that the barrier layer was formed between the first adhesive layer and the half-wavelength retardation layer (see FIG. 3).

### Example 4

An optical film laminate was manufactured by the same method as that in Example 1, except that the barrier layer was formed between the half-wavelength retardation layer and the second adhesive layer (see FIG. 4).

### Example 5

An optical film laminate was manufactured by the same method as that in Example 1, except that the barrier layer was formed between the quarter-wavelength retardation layer and the third adhesive layer (see FIG. 5).

### Example 6

An optical film laminate was manufactured by the same method as that in Example 5, except that the thickness of the barrier layer was changed to 2 μm.

### Example 7

An optical film laminate was manufactured by the same method as that in Example 1, except that the thickness of the barrier layer was changed to 5 μm.

### Example 8

An optical film laminate was manufactured by the same method as that in Example 1, except that the thickness of the barrier layer was changed to 0.5 μm.

### Example 9

An optical film laminate was manufactured by the same method as that in Example 1, except that the thickness of the barrier layer was changed to 6.5 μm.

### Comparative Example

An optical film laminate was manufactured by the same method as that in Example 1, except that the barrier layer was omitted.

### Experimental Example

### (1) Reliability Evaluation

The lower protective film was removed from the optical film laminate of Examples and Comparative Examples, and the optical film laminate was attached to a PET film on which a 500 μm aluminum film was deposited by a third adhesive layer, and then sandwiched between 0.5 T glass substrates to prepare an evaluation sample.

The evaluation sample was placed in an oven (ESPEC, model name: PU-2KT) with 85° C. and 85% relative humidity for 250 hours, and then corrosion of the aluminum thin film was detected (O: no corrosion, Δ: local corrosion detected, X: corrosion detected)

### (2) Evaluation of Iodine Transfer

The optical film laminate of each of Examples and Comparative Examples was sandwiched between the 0.5 T glass substrates to prepare an evaluation sample.

The evaluation sample was left in an oven (ESPEC, model name: PU-2KT) under a relative humidity of 85% at 85° C. for 250 hours, and then the iodine content contained in the third adhesive layer was measured using a TOF-SIMS analysis.

Measurement conditions are as follows.

i) Equipment: TOF.SIMS 5 (Münster, Germany)

ii) Bi3+ Gun/30 keV, 0.6 pA/Raster Size 100 μm*100 μm

Specifically, each peak was normalized to total intensities of peaks corresponding to all ions detected by the TOF-SIMS analysis, and then a peak intensity of iodine ions was confirmed.

The evaluation results are shown in Table 1 below.

TABLE 1

| | position | thickness | | |
|---|---|---|---|---|
| | of | of barrier | | iodine |
| | barrier | layer | | transfer |
| | layer | (μm) | reliability | (*10⁻⁴ counts) |
| Example 1 | FIG. 1 | 3.5 | ◯ | 1.65 |
| Example 2 | FIG. 2 | 3.5 | ◯ | 1.74 |
| Example 3 | FIG. 3 | 3.5 | ◯ | 1.91 |
| Example 4 | FIG. 4 | 3.5 | ◯ | 1.88 |
| Example 5 | FIG. 5 | 3.5 | ◯ | 1.98 |
| Example 6 | FIG. 5 | 2.0 | ◯ | 2.12 |
| Example 7 | FIG. 1 | 5.0 | ◯ | 2.37 |
| Example 8 | FIG. 1 | 0.5 | Δ | 3.28 |
| Example 9 | FIG. 1 | 6.5 | Δ | 3.33 |
| Comparative | — | — | X | 10.2 |
| Example | | | | |

Referring to Table 1, the amount of the iodine transfer was significantly reduced as the barrier layer was inserted, and the iodine blocking was effectively implemented as the barrier layer was included in the position of Example 1.

Referring to Examples 6 to 9, the iodine blocking was significantly increased in the barrier layer having an appropriate thickness range (e.g., 3 μm or more and less than 5 μm).

1. An optical film laminate comprising:
a retardation layer;
a polarizing layer stacked on the retardation layer; and
a barrier layer disposed between the retardation layer and the polarizing layer, or under the retardation layer.

2. The optical film laminate of claim 1, wherein the retardation layer comprises a first retardation layer including a half-wavelength retardation layer and a second retardation layer including a quarter-wavelength retardation layer.

3. The optical film laminate of claim 2, further comprising a first adhesive layer formed between the polarizing layer and the first retardation layer, and a second adhesive layer formed between the first retardation layer and the second retardation layer.

4. The optical film laminate of claim 3, wherein the barrier layer is disposed between the second adhesive layer and the second retardation layer.

5. The optical film laminate of claim 3, wherein the barrier layer is disposed between the polarizing layer and the first adhesive layer.

6. The optical film laminate of claim 3, wherein the barrier layer is disposed between the first adhesive layer and the first retardation layer.

7. The optical film laminate of claim 3, wherein the barrier layer is disposed between the first retardation layer and the second adhesive layer.

8. The optical film laminate of claim 3, further comprising a third adhesive layer formed on a bottom surface of the second retardation layer.

9. The optical film laminate of claim 8, wherein the barrier layer is disposed between the third adhesive layer and the second retardation layer.

10. The optical film laminate of claim 8, wherein an amount of iodine in the third adhesive layer measured by a time-of-flight secondary ion mass spectrometry (TOF-SIMS) after being left for 250 hours at 85° C. and a relative humidity of 85% is 3.5×10⁻⁴ counts or less.

11. The optical film laminate of claim 8, wherein an amount of iodine in the third adhesive layer measured by a time-of-flight secondary ion mass spectrometry (TOF-SIMS) after being left for 250 hours at 85° C. and a relative humidity of 85% is 2.4*10⁻⁴ counts or less.

12. The optical film laminate of claim 1, wherein a thickness of the barrier layer is in a range from 1 to 7 μm.

13. The optical film laminate of claim 1, wherein the barrier layer includes a cycloaliphatic acrylic resin.

14. The optical film laminate of claim 1, wherein the polarizing layer includes a polyvinyl alcohol (PVA) polarizer dyed with iodine, and the barrier layer serves as an iodine migration blocking layer.

15. An image display device, comprising:
a display panel; and
the optical film laminate of claim 1 stacked on the display panel.

16. The image display device of claim 15, further comprising a touch sensor layer disposed between the display panel and the optical film laminate.
